(19) United States
(12) Patent Application Publication
(10) Pub. No.: US 2006/0249279 A1
(43) Pub. Date: Nov. 9, 2006

(54) Method and apparatus for electronics cooling

(76) Inventors: Lalit Chordia, Pittsburgh, PA (US); John Davis, Pittsburgh, PA (US); Stephan Fatschel, Seven Fields, PA (US); Robert Panella, New Kensington, PA (US); Brian Moyer, Pittsburgh, PA (US)

Correspondence Address: MEYER UNKOVIC & SCOTT LLP, 1300 OLIVER BUILDING, PITTSBURGH, PA, 15222, US

(21) Appl. No.: 11/395,819

(22) Filed: Mar. 31, 2006

Related U.S. Application Data
(63) Continuation-in-part of application No. 10/702,396, filed on Nov. 5, 2003, now abandoned.
(60) Provisional application No. 60/424,142, filed on Nov. 5, 2002.

(51) Int. Cl. H05K 7/20

(52) U.S. Cl. 165/80.4; 361/699; 257/714

(57) ABSTRACT

A method and apparatus for actively cooling a device, space or circuit board are disclosed. The device may be an electrical or electronic component that includes an integrated circuit or embedded control. The apparatus employs a fluid in a closed loop, at least two heat exchangers and a fluid driver.

### CROSS-REFERENCE TO RELATED APPLICATIONS:

This application is a continuation-in-part of U.S. non-provisional patent application Ser. No. 10/702,396 filed on Nov. 5, 2003, which itself claims priority to U.S. provisional patent application Ser. No. 60/424,142 filed Nov. 5, 2002. This application also claims priority to U.S. non-provisional patent application Ser. No. 11/198,889 filed Aug. 5, 2005, which is also a continuation-in-part of U.S. non-provisional patent application Ser. No. 10/702,396. All of the above-referenced applications are incorporated herein by reference.

### FIELD OF THE INVENTION

The invention generally relates to cooling systems and more particularly relates to an active cooling system and method that employs a fluid near or above its critical pressure, and also relates to a small-scale apparatus utilized to operate such a cycle. Typical target applications include, for example, cooling of printed circuit boards, computers, computer components, analytical and laboratory equipment, lasers, and remote sensing equipment.

### BACKGROUND OF THE INVENTION

The cooling of devices such as computers, servers, telecommunications switchgear and numerous other types of electronic and medical instrumentation has been an intense area of research for quite some time. The need for increased performance, together with ever increasing compactness, has led to the need for increased levels of heat dissipation from these devices. Integrated circuits work faster, more reliably, and with less current leakage if their temperature is kept as low as possible. The heat emitted by these circuits can overwhelm the cooling capacity of conventional air-blown heat sinks, especially for example in the cases of thin-profile apparatuses such as laptop computers and stacked server boards. Another method of improving a heat sink is to construct it as a thermoelectric cooler, known as a Peltier cooler, which enables the temperature at the junction with the heat source to be substantially below the temperature of the heat source itself. However, Peltier coolers require more input power than can be dissipated and are therefore an inefficient means of refrigeration because more heat is added than is removed.

Microchannel heat exchangers through which a pumped fluid flows can take the place of conventional air-blown heat sinks. In such cases, the heat exchanger could be placed atop an integrated circuit so as to cool it directly. Liquid coolant within the microchannel heat exchanger would be impelled toward a secondary heat-rejecting heat exchanger by pumping, capillary action, thermo-syphoning, electrohydrodynamic or other means of fluid flow and returned to the microchannel heat exchanger as coolant. The small size of the channels allows for high pressure operation, which widens the possibilities for heat-transfer fluids to use in the system.

Alternatively, heat from integrated circuits can be drawn from within the printed-circuit boards upon which they are mounted by means of thin heat sinks that are laminated into the boards themselves. Until now, these heat sinks have been passive components that conduct heat to an external heat exchanger, which is typically cooled by countercurrent air, such that they supplement the function of a heat-sink that is mounted on top of an integrated circuit. Examples are found in U.S. Pat. No. 6,288,906 and others which describe the use of conductive vertical posts, or “thermal vias” to transport heat to metallic planes that are typically located on the top or back side of a printed circuit board. This metallic plane can serve a primary function as the electrical ground for the board. Blish et al. U.S. Pat. No. 6,518,661 takes this concept a step further by connecting internal conductive planes first with one set of thermal vias that run down from the heat-generating elements, then with another set of thermal vias that run up to an air-blown heat sink that is mounted some distance away from the integrated circuit. All of these inventions are limited by the thermal conductivity of the transporting media, which in turn is limited by the temperature difference that can be achieved between the conductive media and cooling air. The present invention improves upon these techniques by providing a method and apparatus for transporting a working fluid through a thin structure, and in, for example, a laminate within a printed circuit board or other type of thin, heated structure.

Microchannels pose a problem of fluid drag that is best overcome, as disclosed in the present invention, by a pumping means to drive the fluid through the heat exchanger. Examples exist that relate to the pumping of gases and liquids, and especially polar fluids such as water. An example is found in Goodson et al. (U.S. Publication No. 2003/0062149) regarding pumping liquids by electro-osmotic means. The invention of Goodson et al., however, is limited to fluids that have a hydrogen-ion, and thus a pH, content. The present invention overcomes this limitation with the use of a non-polar fluid, such as carbon dioxide that has no hydrogen-ion content and thus no pH.

U.S. Patent No. 6,530,420 to Takeda et al. describes using carbon dioxide in a passive thermo-siphoning system. This system, however, is based on different densities of the fluid, depending on pressure, and thus is pressure-dependent. Because Takeda et al. has no means for propelling the fluid the system is limited in its capacity. Furthermore, the system is limited in its physical configuration in that it must maintain a particular orientation with respect to the earth's center of gravity. The present invention overcomes this limitation of pressure dependence and physical orientation by the design of an active cooling system with a fluid driver.

### SUMMARY OF THE INVENTION

An object of the present invention is to provide an apparatus for actively cooling a device or space using a non-lubricated fluid.

Another object of the present invention is to provide a method for actively cooling a device or space using carbon dioxide that is near or above its critical pressure. Yet another object of the present invention is to provide a method and apparatus for heat removal from within circuit boards.

Specifically, what is provided is an apparatus for actively cooling a heat-emitting device or space comprising a heat accepting microchannel heat exchanger located in thermal contact with said heat-emitting device, wherein said heat-emitting device is selected from the group consisting of electrical and electronic components comprising at least an integrated circuit or embedded control, wherein said heat accepting microchannel heat exchanger has at least one profile in the range of 30 millimeters to 0.2 millimeters. The term profile within this application means a dimension whether being width, length, depth or thickness. The invention further includes a heat rejecting heat exchanger, wherein a tube is in fluid connection with said heat accepting microchannel heat exchanger and with said heat rejecting heat exchanger thereby creating a sealed, closed cooling system; a lubricant-free fluid, which can be carbon dioxide, is disposed within the tube, wherein said lubricant-free fluid comprises thermally conductive particles to increase cooling performance; a fluid driver is disposed along said tube for circulating said lubricant-free fluid to provide cooling; and wherein said fluid driver is located in fluid connection between said heat accepting heat exchanger and said heat rejecting heat exchanger. The apparatus also includes a means of fluid flow from the fluid driver that is electrical, electromechanical, mechanical or magnetic. The apparatus further provides a controller for monitoring the apparatus. The control can be provided by hardware, software or by some other means. The power for the apparatus is derived from the group consisting of a public power network of the device and an independent power source. The heat accepting microchannel heat exchanger can be integrated into the packaging of the heat-emitting device. The apparatus at the present invention has at least one profile with dimensions in the range of 1 millimeter to 0.4 millimeters, preferably with dimensions less than 1 millimeter and more preferably with dimensions less than 0.4 millimeters.

The invention also provides a method of actively cooling a heat-emitting device, wherein said heat-emitting device is selected from the group consisting of electrical or electronic components comprising at least an integrated circuit or embedded control, comprising the steps of transferring heat from a heat-emitting device to a heat accepting microchannel heat exchanger; locating said heat accepting microchannel heat exchanger in thermal contact with said heat-emitting device; transferring heat from said heat accepting microchannel heat exchanger to a lubricant-free, fluid; wherein said lubricant-free fluid is carbon dioxide near or above its critical pressure, transferring heat from said lubricant-free fluid to a heat rejecting heat exchanger; circulating said lubricant-free fluid by means of a fluid driver; and varying said flow rate of said lubricant-free fluid according to a temperature of said heat-emitting device, wherein said varying of said flow rate is achieved by actuation using electrical, electromechanical, mechanical or magnetic means.

The method also includes the step of regulating said cooling method using a controller which is either software or hardware. The method also includes the step of adding thermally conductive particles to said fluid to increase cooling performance.

The invention also discloses a method of removing heat from a circuit board consisting of flowing a fluid into and through a circuit board within a series of microchannels; wherein said fluid is near or above its critical point and wherein said fluid can be carbon dioxide and is lubricant fluid-free, transferring heat from said circuit board to said fluid by means of a heat exchanger; transferring heat from said fluid to an external environment by means of a second heat exchanger; providing a fluid driver to circulate said fluid; and varying a flow rate of said fluid according to the temperature of said circuit board.

This method allows heat to be removed from multiple sources on the circuit board.

The invention also provides an apparatus for removing heat from a circuit board comprising a heat accepting heat exchanger having a plurality of microchannels located within said circuit board; a fluid disposed within said microchannels; a fluid driver to impel said fluid through said microchannels; a second heat rejecting heat exchanger for exhausting heat to the environment; and both heat exchangers disposed in fluid connection with said fluid driver.

The apparatus above for removing heat from a circuit board, wherein the heat exchanger disposed within said circuit board comprises microchannels having a depth of less than 500 micro meters. The apparatus above wherein said heat exchanger disposed within said circuit board has at least one profile in the range of 30 millimeters to 0.2 millimeters. The term profile within this application means a dimension whether being width, length, depth or thickness. The apparatus wherein said heat exchanger disposed within said circuit board has at least one profile in the range of 1 millimeter to 0.4 millimeters.

The apparatus above wherein said heat accepting heat exchanger is formed from materials selected from the group consisting of metallic, ceramic, polymeric and a combination thereof. The apparatus wherein the fluid at or above its critical point is selected from the group consisting of water, carbon dioxide, ammonia, sulfur dioxide, chlorofluorocarbon, hydrofluorocarbon, hydrocarbon and a combination thereof.

The fluid in the above apparatus can be carbon dioxide and can also be lubricant-free. The above-listed fluid driver is selected from the group consisting of a pump, compressor and a combination thereof. This apparatus can remove heat from multiple sources on said circuit board. The circuit board of which heat is being removed has a thermal vias.

### BRIEF DESCRIPTION OF THE FIGURES

The figures are provided to illustrate some of the embodiments of this invention. It is envisioned that alternate configurations of the embodiments of the present disclosure maybe adopted without deviating from the invention as illustrated in these figures.

FIG. 1 displays a schematic representation of the cooling system of the present invention for electronics cooling that utilizes a pump.

FIG. 2 presents an overall schematic of a pumped cooling system as in FIG. 1, showing a printed circuit board through which a microchannel heat exchanger is placed.

FIG. 3 discloses a printed circuit board having a central heat-emitting processor, along with peripheral surface-mounted devices, and with a thin-plate microchannel heat exchanger laminated within. Cross-sectional detail A shows a pattern of microchannels emerging from the end of the board.

FIG. 4 describes the microchannel construction in cross-sectional view.

FIG. 5 shows the positioning of a microchannel heat exchanger, in cross-sectional view, within a printed circuit board

FIG. 6 presents performance data for a thin microchannel cooling system.

FIG. 7 depicts a typical server mother board, showing the positions of heat-generating integrated circuits, with the route of embedded heat-accepting microchannels shown in a shaded path.

### DETAILED DESCRIPTION OF THE FIGURES

The invention will now be described in detail in relation to a preferred embodiment and implementation thereof which is exemplary in nature and descriptively specific as disclosed. As is customary, it will be understood that no limitation of the scope of the invention is thereby intended. The invention encompasses such alterations and further modifications in the illustrated method and apparatus, and such further applications of the principles of the invention illustrated herein, as would normally occur to persons skilled in the art to which the invention relates.

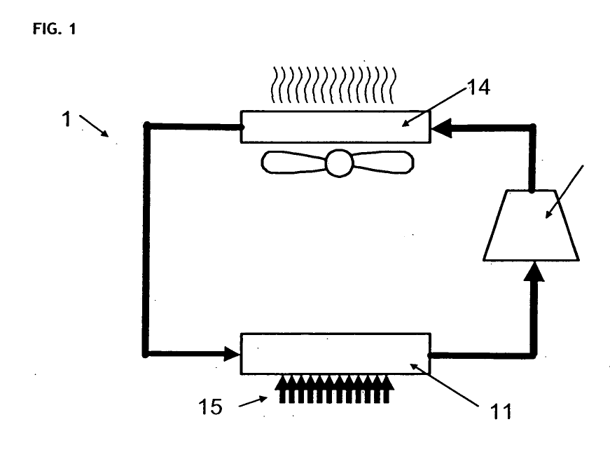

And now, referring to FIGS. 1-7, the present invention provides a method and apparatus for active cooling using a fluid near or above its critical pressure. In a preferred embodiment, the present invention provides a method and apparatus for actively cooling an electrical or electronic device, and other devices and components having at least an integrated circuit or embedded control, using a fluid near or above its critical pressure. A fluid that is below the critical pressure is at least partially liquid when it enters the microchannels and then evaporates to a gas during passage through the microchannels. A fluid that is above the critical pressure is in a gas-like supercritical state throughout its passage through the microchannels. The cooling methods disclosed herein relate to a sealed, closed loop for circulation of a fluid that is devoid of hydrogen ion content, and preferably a fluid that is near or above its critical point and devoid of hydrogen ion content. The cooling system is comprised of at least two heat exchangers and includes a fluid driver. All components of the cooling system are connected within a closed circuit and may be integrated into one package or container, distributed throughout the device to be cooled, or located in a package that contains the device to be cooled. The cooling system may also have its own container. An example of a container that includes a device to be cooled would be a rack-mounted server box. The invention provides a means of cooling devices, including, but not limited to, electrical and electronic devices, and other devices and components having at least an integrated circuit or embedded control. Examples of such devices include but are not limited to electrical, electronic or optical elements within an appliance or the appliance itself, with at least an integrated circuit, embedded control or other element that generates heat, including for example computers, servers, telecommunications switchgear, radio frequency devices, lasers and numerous other types of electronic equipment, medical equipment, military hardware and many more similar items that are generally compact in design. In another embodiment the present invention may be used to cool space or an enclosed location, such as in a portable cooler.

In its basic operation, the invention causes a cooling fluid to circulate between a heat accepting heat exchanger, where heat is absorbed from the device being cooled, and a heat rejecting heat exchanger, where the absorbed heat from the device is discharged, thereby cooling the fluid so that it can re-circulate to the heat accepting heat exchanger and the process continues. The fluid flows through small microchannels of less than 1 millimeter in width or diameter. Because of frictional forces within these microchannels, the fluid must be impelled in some manner. The heat rejecting heat exchanger of the present invention is the type that causes heat from the apparatus' fluid to transfer to an ambient media, typically air. In another preferred embodiment the ambient media is a liquid. The heat accepting heat exchanger of the present invention is a heat exchanger that is in direct or indirect contact with the device to be cooled.

The apparatus of the present invention can be placed in direct contact with the device to be cooled. Alternatively, a thermal grease can be placed in between the device to be cooled and the apparatus. This thermal grease increases the heat transfer coefficient between the device and the apparatus.

According to the present invention, a fluid driver circulates a fluid around the closed circuit and through at least one heat accepting heat exchanger and at least one heat rejecting heat exchanger. The fluid driver can be actuated by electrical, mechanical, electromechanical, magnetic or electromagnetic means. In one preferred embodiment the fluid driver is a compressor. In another preferred embodiment the fluid driver is a pump.

Alternatively, the pump can be mechanical in nature, wherein the immediate driving force that impels the fluid is mechanical, such as the action of a reciprocating piston or a rotating-vane impeller. The force that drives a mechanical pump can itself be electrical in nature, such as an electric motor, in which case the combination of the pump and motor can be described as actuated by electromechanical means.

A further means of fluid flow is magnetic in nature, as in the case of pumping element that moves in response to a changing magnetic field. An example is a piston impeller that moves back and forth with the changing direction of a magnetic field. The magnetic field may result from electrical current flowing through a coil. As the current reverses direction so does the magnetic field and the impeller. Such pumps can be described as magnetically actuated, because the means for actuating the driving element is magnetic.

The present invention exploits some of the properties of a fluid near or above its critical pressure, which enables a reduction in the size of such components as heat exchangers and the fluid driver. These reductions also allow for the process to use less energy. The said fluid may be carbon dioxide, water, air or a natural hydrocarbon. In a preferred embodiment of the present invention, the fluid is carbon dioxide near or above its critical point. Such carbon dioxide near or above its critical point exhibits low viscosity, which eases the load on the fluid driver. Said fluid near or above its critical point is devoid of hydrogen ion content; in other words, there is an absence of pH. This makes it impossible to propel carbon dioxide by electro-osmotic means.

Heat transfer can be further improved by the addition of additives to the fluid, such as thermally conductive nanoparticles. Such additives improve the heat transfer characteristics of the fluid, such as thermal conductivity. In addition, additives can be included to increase the heat capacity of the fluid, which helps in reducing the flow rate of the fluid required to cool a certain heat load.

Another way to improve heat transfer is to limit or eliminate lubricants that might be contained in the fluid. Such lubricants might leak from the fluid driver or be added to the fluid to increase the mechanical performance of the system. Such lubricants may coat the heat transfer area and effectively reduce the heat transfer efficiencies. In a preferred embodiment of the present invention, the fluid does not contain any lubricants, making the fluid oil-free.

All of the components and interconnections of the apparatus may be connected and sealed into one package. The entire package is contacted with the external surface of a device element and heat is transferred between the device element and the apparatus. In some cases, the components of the cooling apparatus may also be distributed across more than one device element rather than sealed into a single package. For example, a single heat-rejecting heat exchanger might serve all sub-assemblies of an apparatus in a device, not just one of them. Thermal grease can optionally be applied to the device and/or the cooling apparatus, or applied between the device and cooling apparatus to increase the heat transfer coefficient.

In one preferred embodiment, FIG. 1 shows a schematic of the cycle components of the present disclosure. As detailed in the figures, the apparatus is comprised of a pump 13, heat rejecting heat exchanger 14 and heat accepting heat exchanger 11 in a closed loop with all components connected. Said apparatus has a regulating means and sensors to monitor and control performance and environmental conditions. For example, a sensor can relay temperature information to a control mechanism or software that in turn causes the pump to increase or decrease speed so as to vary the rate of fluid flow, and by consequence, the rate of heat dissipated by the apparatus. If the temperature is too high, fluid flow is increased; if the temperature is too low, fluid flow is decreased. Any method of control can be integrated into the cooling device.

Power to said apparatus may be derived from the public net of the device or from an independent source. A public net is a circuit contained within the device that derives electric power from a power source that is also contained within the device. It supplies power to all components of the device, hence its description as “public” within the device itself. Such internal power sources typically rectify power that is available from commercial nets. The apparatus as disclosed herein may derive power internally from the public net, or it may be supplied by a separate electrical connection to an independent, commercial net.

The apparatus contacts the packaging of the integrated circuit and the heat accepting heat exchanger 11 is near to or in contact with the device being cooled. The heat accepting exchanger 11 of the system faces toward the packaging of the device and is directly in thermal contact with it. The heat accepting heat exchanger 11 may be located in any position relative to the device, for example above or below the heat source 15, and it may have any suitable configuration. A grease, thermal grease or heat-conducting material may be used to facilitate transfer of heat between the device to be cooled and the heat accepting heat exchanger 11 as well as to secure any element in place. The heat rejecting heat exchanger 14 may be located in any position relative to the device and may have any suitable configuration. A fan that is directed toward the heat rejecting heat exchanger 14 may optionally be used to discharge heat from the closed loop. In another preferred embodiment, a fan may be placed on the other side of the heat rejecting heat exchanger 14 to draw the heat away from the heat rejecting heat exchanger 14.

In a preferred embodiment of the present invention, the heat exchangers used in the apparatus are of a microchannel type, in which case the channel dimensions are less than 1 millimeter, preferably less than 500 micrometers and more preferably less than 200 micrometers in cross-sectional length, width or diameter. The smaller the channel dimension, the larger the wall surface area can be, and hence, the more area there is for heat transfer. Within limits determined by the manufacturability of the channels and the increase in pressure drop, and with it, power to drive the pump, channels should be as small as possible.

In one preferred embodiment of the present invention, the heat-accepting heat exchanger may be integrated into the device, typically as part of the device “package.” For example, the heat-accepting heat exchanger may be contained within the device package in the form of a microchannel heat exchanger that is in direct contact with the integrated circuit itself, so that within the same enclosed space there is no solid surface obstructing the heat transfer from the top or bottom of the element that is emitting heat.

In one embodiment of the present invention, the fluid driver can be in the form of a mechanical pump selected from commercially available models such as Thar Technologies' P-10, P-50 or P-200 Series pumps, or can be designed to suit the specific cooling application.

In another preferred embodiment, a heat rejecting heat exchanger is external to the apparatus but is still connected to the loop of the components. Piping or tubing connects said external heat rejecting heat exchanger to the components within the container or apparatus packaging, providing a means for fluid flow among the components of the cooling apparatus. The external heat rejecting heat exchanger may be located in any position relative to the device. A fan may optionally be attached to the external heat-rejecting heat exchanger and is used to discharge heat from the closed loop.

In electronic devices such as microcomputers, the heat dissipated from an integrated circuit can range from 25 to 1,000 watts, and more typically between 50 and 200 watts. The area available for contact by the heat accepting heat exchanger against such an integrated circuit, or housing of such integrated circuit, can range from 0.1 square inches to nearly 4.0 square inches. This combination of heat dissipation and area available calls for heat accepting heat exchangers that are capable of removing as much as 1,000 watts per square inch, but typically is in the range of 50 to 300 watts per square inch. The flow rate for a fluid above the critical point that is removing heat at this rate can be measured in milliliters per minute. For carbon dioxide, the rate is preferably between 200 and 1,000 milliliters per minute.

There is a plurality of advantages that may be inferred from the present disclosure arising from the various features of the apparatus, systems and methods described herein. It will be noted that other embodiments of each of the apparatus, system and method of the present disclosure may not include all of the features described yet still benefit from at least some of the inferred advantages of such features. Those of ordinary skill in the art may readily devise their own implementations of an apparatus, system and method that incorporate one or more of the features of the present disclosure and fall within the spirit and scope of the disclosure.

### EXAMPLE 1

In the case of carbon dioxide near or above its critical point, the fluid would be maintained at a pressure above 1,070 pounds per sq. in. (absolute). Heat capacity is typically between 0.4 and 1.0 Btu per pound-° R, except near the critical point, at which it can jump up to 30 Btu per pound-° R.

Thermal conductivity increases by a factor of almost four around the critical temperature. These conditions promote efficient heat acceptance and rejection when heat is exchanged against ambient air. The pressure difference between the heat rejecting heat exchanger and heat accepting heat exchanger is that which corresponds to the pressure drop of the apparatus, and can be as low as a few pounds per square inch. This difference is small enough to be overcome with a small fluid driver.

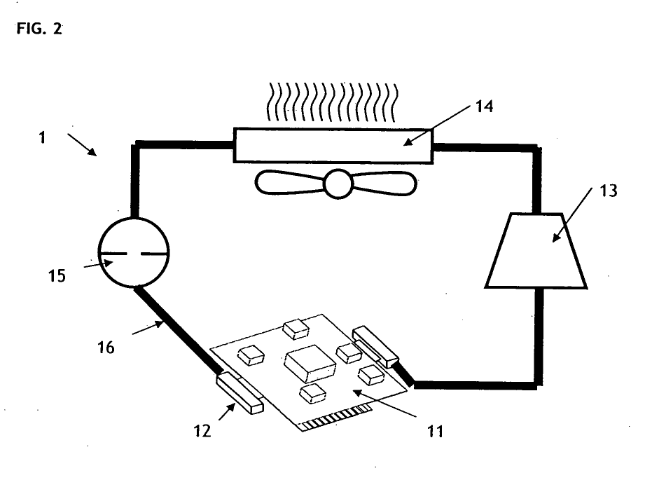

Referring to FIG. 2, the cooling system 1 includes a fluid driver 13 to impel a fluid, a heat accepting heat exchanger 11 that accepts heat picked up from a target device, a heat rejecting heat exchanger 14 that rejects heat absorbed by the heat accepting heat exchanger 11 and the associated piping 16, controls and valves. The cooling apparatus may be used for refrigerating or cooling a target device or location. In the case of refrigeration to sub-ambient temperatures, the fluid driver 13 can optionally be a compressor and a fluid expansion device 15 would be included. The fluid expansion device 15 constricts fluid flow in such a way that higher pressure is maintained between the compressor outlet and through the heat rejecting heat exchanger 14, while lower pressure is maintained from the inlet of the heat accepting heat exchanger 11 to the inlet of the compressor. Such expansion devices may take any of several forms known to the art of refrigeration, and in particular in this invention they may take the form of fixed- or variable-width orifices, as well as capillary tubes of sufficient length to provide adequate pressure drop. In the case of cooling to ambient temperatures, a pump may be used as the fluid driver without the need for a fluid-expansion device.

In another embodiment of the present invention, the cooling system cools a circuit board. A circuit board may be a laminated product, as in a printed circuit board, a single layer construction, such as a ground plane, or a panel, and preferably the circuit board is heat-generating. Any device, circuit board or panel that is heat-emitting shall be construed as heat-generating; likewise, any heat-generating device, circuit board or panel that is heat-generating shall be construed as heat-emitting. For the purposes of this disclosure a circuit board shall be construed as to include any board or panel, including, but not limited to printed circuit boards, ground planes and heat-emitting panels.

The fluid for cooling a circuit board may be any of several types common to heat transfer, including but not limited to water, ammonia, sulfur dioxide, chlorofluorocarbon, hydrofluorocarbon, hydrocarbon, carbon dioxide, or a combination thereof. The fluid used in the system may be in liquid or gaseous state, as well as in a state near or above the critical point of the fluid. In a preferred embodiment the fluid is carbon dioxide near or above its critical point. The circuit board may be made from various materials, including but not limited to metallic, ceramic, polymeric or a combination thereof.

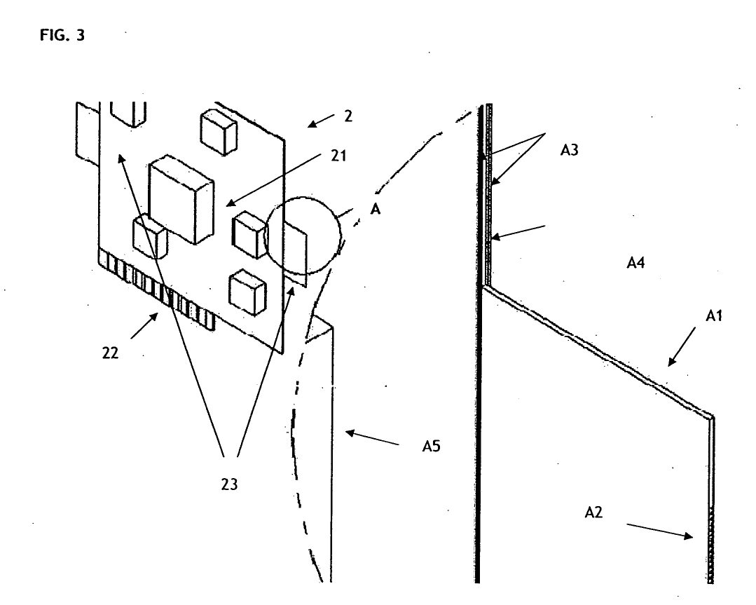

As shown in FIG. 3, a printed circuit board 2 includes a heat-emitting microchip 21, circuit line traces (not shown) mounted on its surface and a tab for electrical connections 22 along one edge. Additional tabs 23 and A1 (in Detail A) are meant for insertion into connectors (not shown) to the heat exchanger A4 that resides within the structure of the laminated board between regular circuit-board laminations A3. At the outer edge of these tabs can be seen the microchannels A2 of the heat accepting heat exchanger A4. Also shown in Detail A is part of one of the surface mounted devices, A5. The heat accepting heat exchanger A4 can reside at any position on or in the board, be it top, bottom or laminated between the top and bottom (as shown). Also, the connection tabs 23 can be relocated to any other position along the edges of the printed circuit board, or they can be replaced entirely by connections that are placed on the top or bottom surface of the board. FIG. 2 merely represents one example of a board configuration. This invention is not limited to that particular board configuration. What is common to all configurations, however, is that the heat accepting heat exchanger has a thin profile. At least one the profiles, as that term is defined above, of the heat accepting heat exchanger is in the range from 30 millimeters to 0.2 millimeters and preferably in the range of 1 millimeter to 0.4 millimeters. A profile of 0.4 millimeters is similar to the thickness of copper-clad laminates that make up most of the printed circuit board structure. The heat exchangers may be formed of materials from the group consisting of metallic, ceramic, polymeric or a combination thereof.

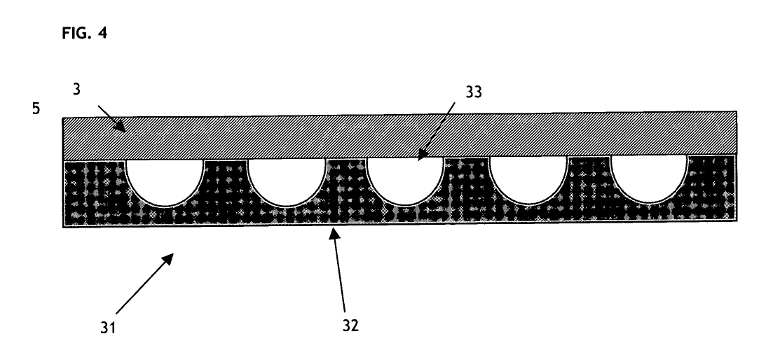

FIG. 4 shows a cross section of the heat accepting heat exchanger 3. The heat accepting heat exchanger 3 consists of a substrate 31 onto which the microchannels 32 are formed and a top layer 33 that bonds to the unpatterned areas of the substrate to form a capping layer above the microchannels. Channels can be straight or meandering. They may be formed by any of several methods known to the art of image transference onto surfaces. The path followed by the channels can optionally follow a pattern that is transferred from a drawing or photograph, as in the cases of photolithography and embossing.

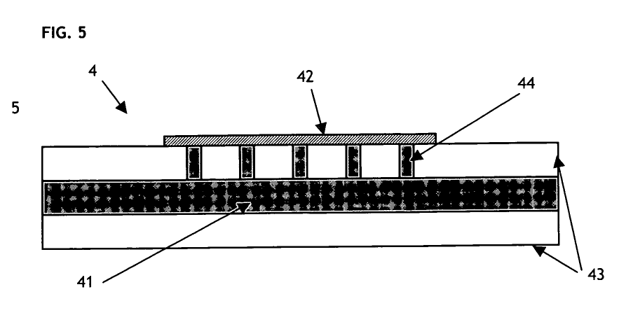

FIG. 5 shows a cross-sectional view of a printed circuit board 4. The heat accepting heat exchanger 41 is positioned with its microchannels passing under an integrated circuit 42 that is mounted on top of the board. The heat accepting heat exchanger 41 forms one of the lamination layers that make up the entire printed circuit board 4. In the embodiment shown in FIG. 5, the heat accepting heat exchanger 41 is separated from the integrated circuit 42 by at least one laminated layer of epoxy or other electrically insulating media 43, through which an array of thermal vias 44 facilitates direct contact with the heat-emitting device that is mounted on top of the board, which can be an integrated circuit, through vertical, thermal conductors.

The heat accepting heat exchanger may be positioned within a circuit board as any layer in the lamination process. Furthermore, it may be added to the top or bottom sides of a circuit board. Thermal vias contribute greatly to the transference of heat from the heat-emitting devices to the heat accepting heat 41 exchanger within the board. Thermal vias, as shown in FIG. 5, may be present in the printed circuit board but are not a required condition.

The cooling system of the present invention can withstand internal pressures that may be encountered with heat-transfer fluids undergoing evaporation as they absorb heat, or might be encountered as a result of a pressure differential that develops between the inlet and the outlet of the microchannel array. Included in this group of fluids are such environmentally benign materials as water and carbon dioxide.

### EXAMPLE 3

A heat accepting heat exchanger measuring 100×100 millimeters square and 0.011 inches in thickness is constructed with an array of 80 microchannels running through the center of the lamination, from one side to the opposite side, and laminated into a printed circuit board configuration of layers with FR-4 epoxy insulation. The channels measured nominally 200 microns wide by 100 microns deep and were separated by a distance of nominally 100 microns. In the center of the board was a heat source measuring 27×27 millimeters. The heat accepting heat exchanger was separated from direct contact with the heat source by the distance of one layer of FR-4 but was in indirect contact with the heat source through a square array of 81 thermal vias.

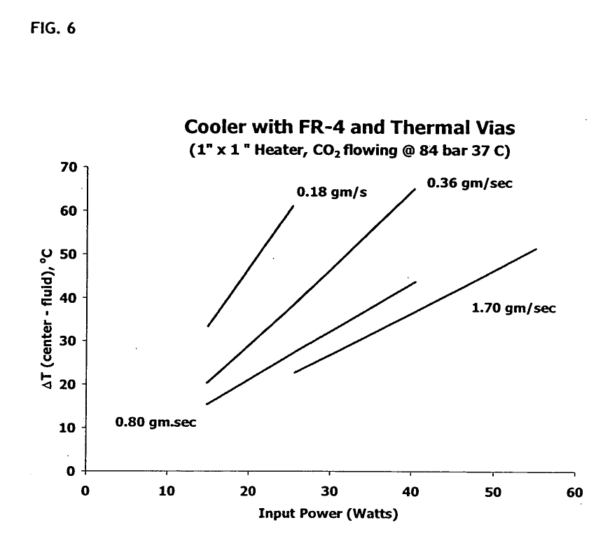

Heat emitted by the heater was from 15-55 watts. Carbon dioxide from a pressurized tank was directed into this heat accepting heat exchanger by a fluid driver at 84 bar and 37° C. inlet temperature, and at flow rates ranging between 0.18 and 1.70 gm per second. As shown in FIG. 6, the temperature at the center of the heat source can be controlled to under 90° C., which corresponds to a temperature difference between the center junction of the hot chip and the fluid flowing though microchannels (represented as the y-axis of FIG. 6) of about 53° C., at a CO₂ flow rate as low as approximately 0.65 gm/second, given a heating rate of 40 watts. Pressure drop at this flow rate is approximately 20 psi.

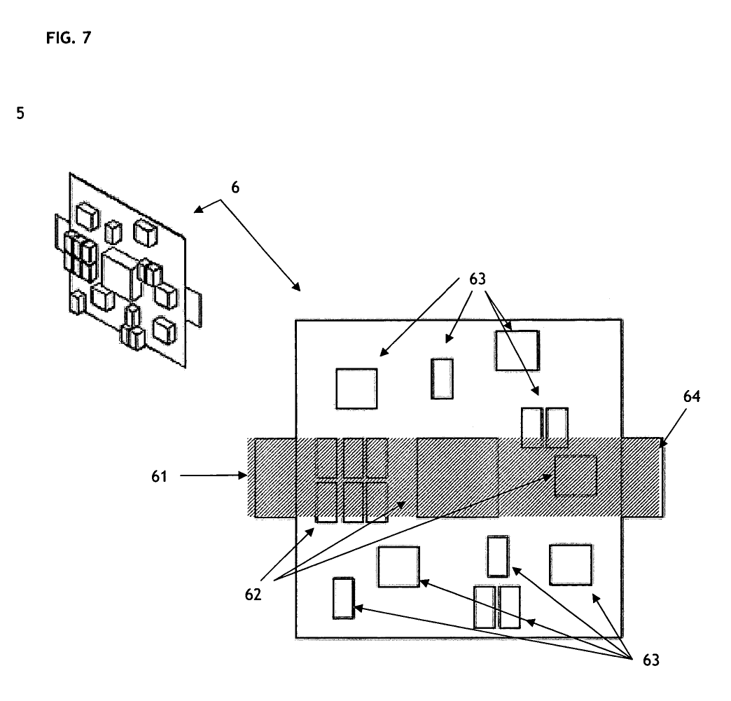

In another preferred embodiment a straight-line configuration of microchannels in the heat accepting heat exchanger may serve more than one integrated circuit on a circuit board. FIG. 7 shows a layout of chips on a printed circuit board 6. The printed circuit board 6 holds an assortment of integrated circuits. The integrated circuits 62 that are above the path of the microchannels are cooled. The other integrated circuits 63 may not be directly cooled by the single run of microchannels; however, more than one group of microchannels is feasible, such that chips 63 are also cooled. Given the heat-removal capability of just one such bundle of microchannels, as demonstrated in the example, it is possible to remove most of the heat dissipated by surface-mounted devices on a printed circuit board.

One way to expose the microchannels outward of a printed circuit board is by means of connection tabs 61 (inlet) and 64 (outlet). These are positioned at opposite edges of the heat accepting heat exchanger because the single run of microchannels is spread directly across the printed circuit board 6. In another embodiment, the microchannels may be directed in a broad 90-degree sweep across the board, such that the connection tabs are on adjacent edges. Alternatively, the microchannels could be turned around by 180 degrees and exit along the same edge as the inlet. Connecting through tabs on edges of the heat accepting heat exchanger is one method for passing fluid to and from the heat accepting heat exchanger. Edge connection tabs do have the advantage of taking up only a small amount of space and allow installation onto boards that are typically placed in slots on mounting racks. Connection tabs can also be mounted on the surface.

The heat accepting heat exchanger is connected to the rest of the cooling system first by connectors that either deliver and distribute fluid to the microchannels at one end of the channel array and then gather the fluid at the discharge end. The connector is joined to the heat accepting heat exchanger in any suitable manner, including but not limited to, clamping or soldering.

Connectors lead into pipes or tubes that direct flow to other system components: a fluid-driving pump or compressor to impel the fluid throughout the system; a heat rejecting heat exchanger for purposes of expelling heat to the environment; and in the case of sub-ambient refrigeration, an expansion device to relieve the pressure of the heat-transfer fluid and drive its temperature lower. The heat rejecting heat exchanger need not be of a microchannel design and typically uses blown air as a medium for cooling the fluid. The location of the fluid driver depends on the thermodynamic conditions desired at different points in the loop. In a preferred embodiment, the fluid driver is located downstream of the heat accepting heat exchanger and upstream from the heat rejecting heat exchanger.

We claim:

1. An apparatus for actively cooling a heat-emitting device or space comprising:
a heat accepting microchannel heat exchanger located in thermal contact with said heat-emitting device; wherein said heat accepting microchannel heat exchanger has at least one profile in the range of 30 millimeters to 0.2 millimeters;
a heat rejecting heat exchanger; wherein a tube connects said heat accepting microchannel heat exchanger to said heat rejecting heat exchanger thereby creating a sealed, closed cooling system;
a lubricant-free fluid disposed within said tube;
a fluid driver disposed along said tube for circulating said lubricant-free fluid to provide cooling; and wherein said fluid driver is located between and in fluid connection with said heat accepting microchannel heat exchanger and said heat rejecting heat exchanger.

2. The apparatus of claim 1, wherein said heat-emitting device is selected from the group consisting of electrical and electronic components comprising at least an integrated circuit or embedded control.

3. The apparatus of claim 1, wherein a fluid flow means produced by said fluid driver is selected from the group consisting of electrical, electromechanical, mechanical and magnetic flows.

4. The apparatus of claim 1, wherein said lubricant-free fluid is carbon dioxide near or above its critical pressure.

5. The apparatus of claim 1, further comprising a controller to monitor said apparatus.

6. The apparatus of claim 1, wherein a power source is selected from the group consisting of a public power network of the device and an independent power source.

7. The apparatus of claim 1, wherein said heat accepting microchannel heat exchanger is integrated into packaging of said heat-emitting device.

8. The apparatus of claim 1, wherein said lubricant-free fluid further comprises thermally conductive particles to increase cooling performance.

9. The apparatus of claim 1, wherein said heat accepting microchannel heat exchanger has at least one profile in a range of 1 millimeter to 0.4 millimeters.

10. The apparatus of claim 1, wherein said heat accepting microchannel heat exchanger has a profile of less than 1 millimeter.

11. The apparatus of claim 1, wherein said heat accepting microchannel heat exchanger has a profile of less than 0.4 millimeters.

12. A method of actively cooling a heat-emitting device, comprising the steps of:
transferring heat from a heat-emitting device to a heat accepting heat exchanger;
locating said heat accepting heat exchanger in thermal contact with said heat-emitting device;
transferring heat from said heat accepting heat exchanger to a lubricant-free fluid;
transferring heat from said lubricant-free fluid to a heat rejecting heat exchanger;
circulating said lubricant-free fluid by means of a fluid driver; and
varying a flow rate of said lubricant-free fluid according to a temperature of said heat-emitting device.

13. The method of claim 12, wherein said heat-emitting device is selected from the group consisting of electrical and electronic components comprising at least an integrated circuit or embedded control.

14. The method of claim 12, wherein said varying of said flow rate is achieved by actuation selected from the group consisting of electrical, electromechanical, mechanical and magnetic means.

15. The method of claim 12, wherein said lubricant-free fluid is carbon dioxide near or above its critical pressure.

16. The method of claim 12, further comprising regulating said cooling method using a controller.

17. The method of claim 12, further comprising adding thermally conductive particles to said lubricant-free fluid to increase cooling performance.

18. A method of removing heat from a circuit board comprising:
flowing a fluid into and through said circuit board within a series of microchannels;
transferring heat from said circuit board to said fluid by means of a second heat exchanger;
transferring heat from said fluid to an external environment by means of a heat exchanger;
providing a fluid driver to circulate said fluid; and
varying a flow rate of said fluid according to a temperature of said circuit board.

19. The method of claim 18, wherein said fluid is near or above its critical point.

20. The method of claim 18, wherein said fluid is carbon dioxide.

21. The method of claim 18, wherein said fluid is free of lubricants.

22. The method of claim 18, further comprising removing heat from multiple sources on said circuit board.

23. An apparatus for removing heat from a circuit board comprising:
a heat accepting heat exchanger having a plurality of microchannels located within said circuit board;
a fluid disposed within said microchannels;
a fluid driver for impelling said fluid through said microchannels;
a heat rejecting heat exchanger for exhausting heat to an environment; and
said heat exchangers disposed in fluid connection with said fluid driver.

24. The apparatus of claim 23, wherein said heat accepting heat exchanger disposed within said circuit board comprises microchannels of a depth of less than 500 micro meters.

25. The apparatus of claim 23, wherein said heat accepting heat exchanger disposed within said circuit board has at least one profile in the range of 30 millimeters to 0.2 millimeters.

26. The apparatus as in claim 23, wherein said heat accepting exchanger disposed within said circuit board has at least one profile in the range of 1 millimeter to 0.4 millimeters.

27. The apparatus of claim 23, wherein said heat accepting heat exchanger is comprised of materials selected from the group consisting of metallic, ceramic, polymeric and a combination thereof.

28. The apparatus of claim 23, wherein said fluid is selected from the group consisting of water, carbon dioxide, ammonia, sulfur dioxide, chlorofluorocarbon, hydrofluorocarbon, hydrocarbon and a combination thereof.

29. The apparatus of claim 23, wherein said fluid is near or above its critical point.

30. The apparatus of claim 29, wherein said fluid is carbon dioxide.

31. The apparatus of claim 23, wherein said fluid is lubricant-free.

32. The apparatus of claim 23, wherein the fluid driver is selected from the group consisting of a pump, compressor and a combination thereof.

33. The apparatus of claim 23, wherein heat is removed from multiple sources on said circuit board.

34. The apparatus of claim 23, wherein said circuit board further comprises thermal vias.
